(19) United States
(12) Patent Application Publication
(10) Pub. No.: US 2015/0340483 A1
(43) Pub. Date: Nov. 26, 2015

(54) Group III-V Device Including a Shield Plate

(71) Applicant: International Rectifier Corporation, El Segundo, CA (US)

(72) Inventor: Michael A. Briere, Scottsdale, AZ (US)

(73) Assignee: INTERNATIONAL RECTIFIER CORPORATION

(21) Appl. No.: 14/707,966

(22) Filed: May 8, 2015

Related U.S. Application Data
(60) Provisional application No. 62/001,200, filed on May 21, 2014.

(51) Int. Cl. H01L 29/778; H01L 29/10; H01L 29/40; H01L 29/20; H01L 29/205

(52) U.S. Cl. CPC H01L 29/7787; H01L 29/2003; H01L 29/205; H01L 29/402; H01L 29/1033

(57) ABSTRACT

There are disclosed herein various implementations of a group III-V device including a shield plate. Such a group III-V device includes a substrate, a transition body situated over the substrate, a device channel layer situated over the transition body, and a device barrier layer situated over the device channel layer and producing a device two-dimensional electron gas (2-DEG). The group III-V device also includes a drain electrode coupled to the device barrier layer, and a shield plate, which may be coupled to the drain electrode or may be a floating shield plate. The shield plate is configured to substantially shield the device 2-DEG from charge centers situated over the device barrier layer.

The present application claims the benefit of and priority to a provisional application entitled “Shielded 2-DEG HEMTs,” Ser. No. 62/001,200 filed on May 21, 2014. The disclosure in this provisional application is hereby incorporated fully by reference into the present application.

### BACKGROUND

### I. Definition

As used herein, the phrase “group III-V” refers to a compound semiconductor including at least one group III element and at least one group V element. By way of to example, a group III-V semiconductor may take the form of a III-Nitride semiconductor. “III-Nitride” or “III-N” refers to a compound semiconductor that includes nitrogen and at least one group III element such as aluminum (Al), gallium (Ga), indium (In), and boron (B), and including but not limited to any of its alloys, such as aluminum gallium nitride (AlₓGa₍₁₋ₓ₎N), indium gallium nitride (In_{y}Ga_{(1-y)}N), aluminum indium gallium nitride (AlIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}AsₐP_{b}N_{(1-a-b)} for example. III-N also refers generally to any polarity including but not limited to Ga-polar, N-polar, semi-polar, or non-polar crystal orientations. A III-N material may also include either the Wurtzitic, Zincblende, or mixed polytypes, and may include single-crystal, monocrystalline, polycrystalline, or amorphous structures. Gallium nitride or GaN, as used herein, refers to a III-N compound semiconductor wherein the group III element or elements include some or a substantial amount of gallium, but may also include other group III elements in addition to gallium.

In addition, as used herein, the phrase “group IV” refers to a semiconductor that includes at least one group IV element such as silicon (Si), germanium (Ge), and carbon (C), and may also include compound semiconductors such as silicon germanium (SiGe) and silicon carbide (SiC), for example. Group IV also refers to semiconductor materials which include more than one layer of group IV elements, or doping of group IV elements to produce strained group IV materials, and may also include group IV based composite substrates such as single-crystal or polycrystalline SiC on silicon, silicon on insulator (SOT), separation by implantation of oxygen (SIMOX) process substrates, and silicon on sapphire (SOS), for example.

It is noted that, as used herein, the terms “low voltage” or “LV” in reference to a transistor or switch describes a transistor or switch with a voltage range of up to approximately fifty volts (50V). It is further noted that use of the term “midvoltage” or “MV” refers to a voltage range from approximately fifty volts to approximately two hundred volts (approximately 50V to 200V). Moreover, the term “high voltage” or “HV,” as used herein, refers to a voltage range from approximately two hundred volts to approximately twelve hundred volts (approximately 200V to 1,200V), or higher.

### II. Background Art

In high power and high performance circuit applications, group III-V field-effect transistors (FETs), such as gallium nitride (GaN) or other III-Nitride based high mobility electron transistors (HEMTs), are often desirable for their high efficiency and high-voltage operation. III-Nitride and other group III-V HEMTs operate using polarization fields to generate a two-dimensional electron gas (2-DEG) allowing for high current densities with low resistive losses. Although their high breakdown voltage, high current density, and very low specific on-resistance render group III-V HEMTs potentially advantageous for use in power applications, III-Nitride and other group III-V HEMTs are susceptible to having their performance degraded due to charge trapping.

Charge trapping may result from the presence of charge centers residing in the various material layers used to fabricate the HEMT, as well as at interfaces between those layers. For example, charge centers may be found in or at the interface of the capping, passivation, dielectric, and package material layers overlying the active channel and barrier layers of the group III-V HEMT. Due to the insulating or semi-insulating nature of the layers in which the charge centers may reside, the fields arising from those charge centers are typically not screened from the device 2-DEG and can undesirably increase the on-resistance of the HEMT.

### SUMMARY

The present disclosure is directed to a group III-V device including a shield plate, substantially as shown in and/or described in connection with at least one of the figures, and as set forth in the claims.

### BRIEF DESCRIPTION OF THE DRAWINGS

FIG. 1 shows a cross-sectional view of an exemplary group III-V device including a shield two-dimensional electron gas (2-DEG) configured to shield the device 2-DEG from charge centers situated in the device structure, according to one implementation.

FIG. 2 shows a cross-sectional view of an exemplary group III-V device including a shield layer configured to shield the device 2-DEG from charge centers situated in the device structure, according to one implementation.

FIG. 3A shows a cross-sectional view of an exemplary group III-V device including a shield plate configured to shield the device 2-DEG from charge centers situated in the device structure, according to one implementation.

FIG. 3B shows a cross-sectional view of an exemplary group III-V device including a shield plate configured to shield the device 2-DEG from charge centers situated in the device structure, according to another implementation.

FIG. 4A shows a top view of an exemplary shield plate arrangement configured to shield the device 2-DEG of FIG. 3A and/or FIG. 3B from charge centers situated in the device structure, according to one implementation.

FIG. 4B shows a top view of an exemplary shield plate arrangement configured to shield the device 2-DEG of FIG. 3A and/or FIG. 3B from charge centers situated in the device structure, according to another implementation.

FIG. 5 shows a cross-sectional view of an exemplary group III-V device including a shield plate configured to shield the device 2-DEG from charge centers situated in the device structure, according to another implementation.

FIG. 6A shows a cross-sectional view of an exemplary group III-V device including a shield layer and a shield plate configured to shield the device 2-DEG from charge centers situated in the device structure, according to one implementation.

FIG. 6B shows a cross-sectional view of an exemplary group III-V device including a shield layer and a shield plate configured to shield the device 2-DEG from charge centers situated in the device structure, according to another implementation.

### DETAILED DESCRIPTION

The following description contains specific information pertaining to implementations in the present disclosure. One skilled in the art will recognize that the present disclosure may be implemented in a manner different from that specifically discussed herein. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

As noted above, despite their many desirable performance characteristics, including high breakdown voltage, high current density, and very low specific on-resistance, III-Nitride and other group III-V high electron mobility transistors (HEMTs) are susceptible to having their performance degraded due to charge trapping. As further noted above, charge trapping may result from the presence of charge centers residing in the various material layers used to fabricate the HEMT, as well as at interfaces between those layers. For example, charge centers may be found in or at the interface of the device substrate, transition layers, and buffer layers underlying the active channel and barrier layers of a group III-V HEMT, as well as in or at the interface of the capping, passivation, dielectric, and package material layers overlying the active channel and barrier layers of the group III-V HEMT.

The causes of charge trapping are varied, and may include charge centers formed as point defects in the group III-V material (impurities, vacancies, interstitials, for example) or charge centers in the form of dangling bonds at the various bulk, surface, and layer interfaces. Due to the insulating or semi-insulating nature of the layers in which the charge centers may reside, the fields arising from those charge centers are typically not screened from the device two-dimensional electron gas (2-DEG) and can degrade the transport properties of the high mobility electrons in the device 2-DEG. This can result in increased resistance of the HEMT through reduction in the number of conduction electrons and/or reduction in the mobility of a population of the conduction electrons.

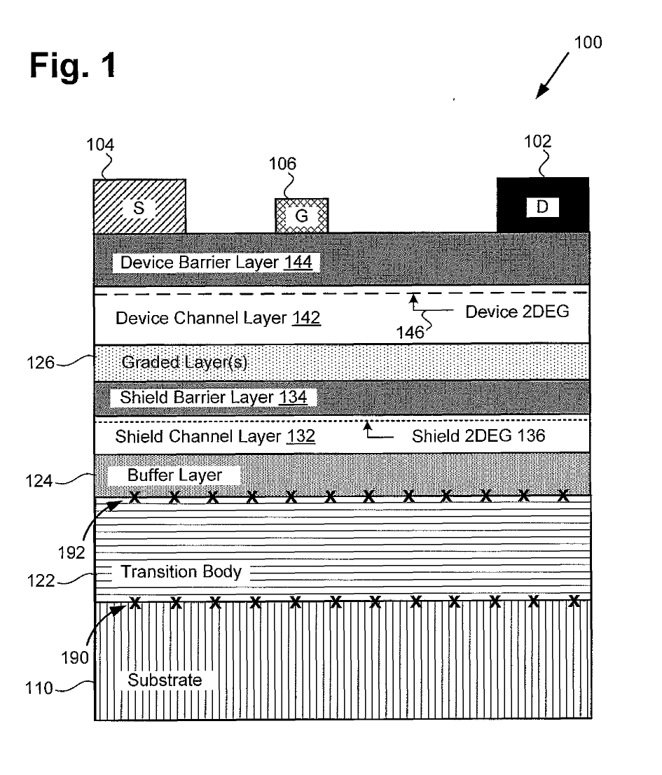

FIG. 1 shows a cross-sectional view of exemplary group III-V device 100 configured to provide shielding from charge centers situated under the device 2-DEG, according to one implementation. As shown in FIG. 1, group III-V device 100 includes substrate 110, transition body 122 situated over substrate 110, and buffer layer 124 situated over transition body 122. In addition, FIG. 1 shows device channel layer 142 situated over transition body 122, and device barrier layer 144 situated over device channel layer 142 to produce device 2-DEG 146. Also shown in FIG. 1 are shield channel layer 132, shield barrier layer 134 situated over shield channel layer 132 to produce shield 2-DEG 136, and graded layer or layers 126 situated between shield barrier layer 134 and device channel layer 142.

Moreover, and as further shown in FIG. 1, group III-V device 100 includes drain electrode 102, source electrode 104, and gate electrode 106, and may have charge centers 190 and/or 192 situated between substrate 110 and device channel layer 142. Drain electrode 102 and source electrode 104 are configured such that they make ohmic contact with device 2-DEG 146. Gate electrode 106 may correspond to a Schottky gate configured to make Schottky contact with device barrier layer 144, or may correspond to an insulated gate configured to couple capacitively to device barrier layer 144. It is noted that group Ill-V device 100 having the features shown in FIG. 1 may be implemented as a III-Nitride or other group III-V HEMT or FET device or hybrid FET/HEMT device.

According to the implementation shown in FIG. 1, device 2-DEG 146 is produced by device barrier layer 144 and device channel layer 142 over graded layer(s) 126, shield barrier layer 134, and shield channel layer 132. As a result, shield 2-DEG 136 produced by shield barrier layer 134 and shield channel layer 132 is situated so as to substantially shield device 2-DEG 146 from charge trapping resulting from the presence of charge centers 190 and 192 below shield 2-DEG 136. That is to say, shield 2-DEG 136 is configured to substantially shield device 2-DEG 146 from charge centers 190 and 192 situated between substrate 110 and shield 2-DEG 136.

Substrate 110 may be formed of any commonly utilized substrate material. For example, substrate 110 may be formed of sapphire, may be a native group III-V substrate, or may be a group IV substrate as described above in the “Definitions” section. Transition body 122 may be formed of multiple III-Nitride or other group III-V layers situated over substrate 110. In some implementations, transition body 122 may take the form of a group III-V body including compositionally graded layers and having different group III-V alloy compositions at respective top and bottom surfaces.

Examples of using compositionally graded transition layers, as well as use of intermediate layers, stress reducing layers, and various interlayers are disclosed in U.S. Pat. No. 6,649,287, entitled “Gallium Nitride Materials and Methods”, filed on Dec. 14, 2000, and issued on Nov. 18, 2003; U.S. Pat. No. 6,617,060, also entitled “Gallium Nitride Materials and Methods”, filed on Jul. 2, 2002, and issued on Sep. 9, 2003; U.S. Pat. No. 7,339,205, entitled “Gallium Nitride Materials and Methods Associated with the Same”, filed on Jun. 28, 2004, and issued on Mar. 4, 2008; U.S. Pat. No. 8,344,417, entitled “Gallium Nitride Semiconductor Structures with Compositionally-Graded Transition Layer”, filed on Jan. 27, 2012, and issued on Jan. 1, 2013; U.S. Pat. No. 8,592,862, also entitled “Gallium Nitride Semiconductor Structures with Compositionally-Graded Transition Layer”, filed on Dec. 27, 2012, and issued on Nov. 26, 2013; U.S. Pat. No. 8,957,454, entitled “III-Nitride Semiconductor Structures with Strain Absorbing Interlayer Transition Modules”, filed on Feb. 24, 2012 and issued on Feb. 17, 2015; U.S. patent application Ser. No. 12/928,946, entitled “Stress Modulated Group III-V Semiconductor Device and Related Method”, filed on Dec. 21, 2010, and published as U.S. Patent Application Publication Number 2012/0153351 on Jun. 21, 2012; and U.S. patent application Ser. No. 11/531,508, entitled “Process for Manufacture of Super Lattice Using Alternating High and Low Temperature Layers to Block Parasitic Current Path”, filed on Sep. 13, 2006, and published as U.S. Patent Application Publication Number 2007/0056506 on Mar. 15, 2007. The disclosures in the above-referenced patents and patent applications are hereby incorporated fully by reference into the present application.

Although not shown in FIG. 1, in some implementations, group III-V device 100 may also include a strain-absorbing layer formed between substrate 110 and transition body 122. Such a strain-absorbing layer may be an amorphous strain-absorbing layer, for example, an amorphous silicon nitride layer. It is noted that in implementations in which substrate 110 is a non-native substrate for device channel layer 142 and device barrier layer 144 (i.e., a non group III-V substrate, such as a silicon or other group IV substrate), transition body 122 is provided to mediate the lattice transition from substrate 110 to buffer layer 124.

In one implementation, transition body 122 may include a nucleation layer (nucleation layer not shown in FIG. 1), in addition to layers formed so as to reduce the net mismatch in thermal coefficient of expansion between substrate 110 and later formed group III-V active layers, such as device channel layer 142 and device barrier layer 144. For instance, when forming a gallium nitride (GaN) based group III-V device, transition body 122 may include an aluminum nitride (AlN) layer formed on substrate 110, or on a strain-absorbing layer and/or a nucleation layer formed on substrate 110, and may further include a series of intermediate layers, such as aluminum gallium nitride (AlGaN) layers having a progressively reduced aluminum content relative to their gallium content, until a suitable transition to a GaN buffer implemented as buffer layer 124 is achieved.

As noted above, in some implementations, transition body 122 may include compositionally graded III-Nitride or other group III-V materials. In such implementations, the specific compositions and thicknesses of the layers included in transition body 122 may depend on the diameter and thickness of substrate 110, and the desired performance of group III-V device 100. For example, the desired breakdown voltage of group III-V device 100, as well as the desired bow and warp of the associated epitaxial wafer supporting fabrication of group III-V device 100 can influence the compositions and thicknesses of the layers used to form transition body 122, as known in the art.

Buffer layer 124 is situated over transition body 122 and may be a III-Nitride or other group III-V material layer formed using any of a number of known growth techniques. For example, in implementations in which group III-V device 100 is a GaN based HEMT, buffer layer 124 may be a compositionally graded GaN based layer. Moreover, in some implementations, buffer layer 124 may take the form of a III-Nitride or other group III-V layer including a group III material having an aluminum concentration in a range from approximately four percent to approximately eight percent, for example an AlGaN layer having such an aluminum concentration. Buffer layer 124 may be formed using any suitable technique for forming III-Nitride or other group III-V based layers, such as molecular-beam epitaxy (MBE), metalorganic chemical vapor deposition (MOCVD), or hydride vapor phase epitaxy (HVPE), to name a few suitable approaches. It is noted that any of MBE, MOCVD, or HVPE, for example, may also be used to form transition body 122.

As shown in FIG. 1, formation of transition body 122 and buffer layer 124 over substrate 110 can result in the inadvertent formation of charge centers 190 and/or 192. Charge centers 190 and/or 192 may be formed as point defects, such as impurities, vacancies, and interstitials, for example, in the group III-V materials used to provide transition body 122 and buffer layer 124. Alternatively, or in addition, charge centers 190 and/or 192 may be present in the form of dangling bonds or other charge trapping sites situated at an interface between substrate 110 and transition body 122, and/or at an interface between transition body 122 and buffer layer 124.

As further shown in FIG. 1, shield channel layer 132 is formed over buffer layer 124, and shield barrier layer 134 is formed over shield channel layer 132 to produce shield 2-DEG 136 configured to substantially shield device 2-DEG 146 from charge centers 190 and 192. Shield channel layer 132 and shield barrier layer 134 may be formed of any group III-V materials suitable for producing shield 2-DEG 136. For example, shield channel layer 132 may be formed as a GaN or indium gallium nitride (InGaN) layer. Shield barrier layer 134 may be formed as a group III-V layer having a larger bandgap than shield channel layer 132, and may take the form of an AlN layer, or an AlGaN layer, for example. Shield channel layer 132 and shield barrier layer 134 may be formed using any of MBE, MOCVD, or HVPE.

Although shield 2-DEG 136 may be a desirable feature of group III-V device 100 for substantially shielding device 2-DEG 146 from charge centers 190 and 192, it is typically undesirable for shield 2-DEG 136 to contribute to the conduction of group III-V device 100. For example, unless suitably isolated from device 2-DEG 146, shield 2-DEG 136 may adversely affect the pinch-off voltage, off-state leakage, breakdown, or otherwise impact the performance or reliability of group III-V device 100. As a result, it may be advantageous or desirable to ensure that neither drain electrode 102 nor source electrode 104 makes ohmic contact with shield 2-DEG 136, and to electrically isolate device 2-DEG 146 from shield 2-DEG 136. According to the implementation shown in FIG. 1, such electrical isolation of device 2-DEG 146 from shield 2-DEG 136 is provided by graded layer(s) 126.

Graded layer(s) 126 may be formed as a single compositionally graded group III-V layer, or as a stack of group III-V layers having different group III-V compositions. Graded layer(s) 126 may be in the range of approximately 0.1 to 2.0 micrometer thick. The compositional grading scheme of graded layer(s) 126 may be continuous or stepped, for example. In some implementations, graded layer(s) 126 may take the form of a compositionally graded III-Nitride or other group III-V layer, or a compositionally graded stack of group III-V layers, including a group III material having an aluminum concentration in a range from approximately four percent to approximately eight percent, for example an AlGaN layer or stack having such an aluminum concentration.

Moreover, in some implementations, it may be advantageous or desirable to form graded layer(s) 126 using an impurity graded scheme as disclosed in U.S. Pat. No. 8,796,738, entitled “Group III-V Device Structure Having a Selectively Reduced Impurity Concentration”, filed on Sep. 5, 2012, and issued on Aug. 5, 2014. This patent is hereby incorporated fully by reference into the present application. Graded layer(s) 126 may be formed using any of MBE, MOCVD, or HVPE.

Device channel layer 142 is formed over graded layer(s) 126, and device barrier layer 144 is formed over device channel layer 142 using any of MBE, MOCVD, or HVPE, for example. In addition a thin group III-V capping layer may be used over device barrier layer 144 (capping layer not shown in FIG. 1). In one implementation, for example, group III-V device 100 may take the form of a III-Nitride HEMT having a GaN layer as device channel layer 142 and an AlGaN layer as device barrier layer 144. It is noted that, in some implementations, the optional capping layer described above may be formed of GaN or AlGaN and may be intentionally doped or may be substantially undoped. However, in other implementations, the optional capping layer may be formed of an insulating material. such as silicon nitride (Si₃N₄), for example.

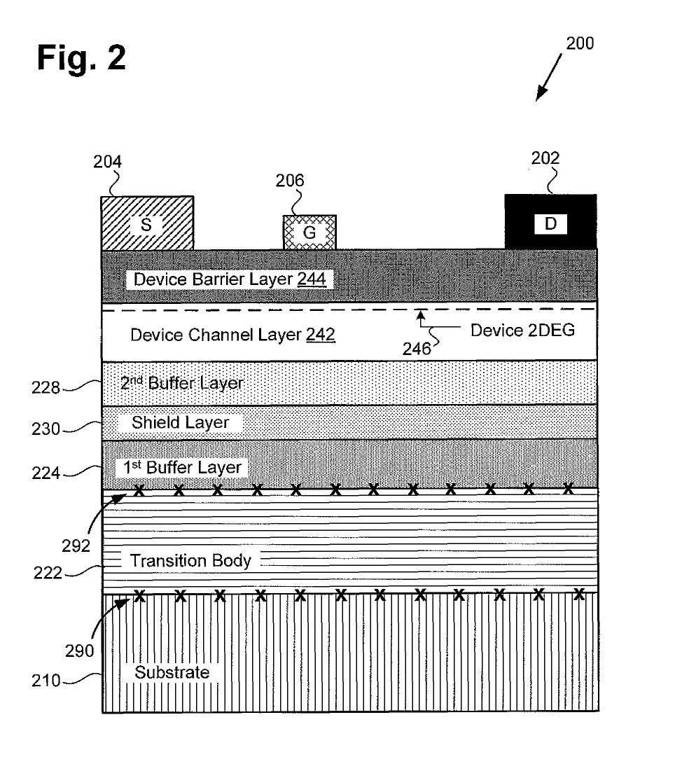

It is further noted that in some implementations, it may be advantageous or desirable to form device barrier layer 144 over a spacer layer (or layers) disposed between device barrier layer 144 and device channel layer 142 (spacer layer or layers also not shown in FIG. 1). Examples of using such spacer layer(s) are disclosed in U.S. Pat. No. 8,659,030, entitled “III-Nitride Heterojunction Devices Having a Multilayer Spacer”, filed on Feb. 15, 2012, and issued on Feb. 25, 2014. This patent is hereby incorporated fully by reference into the present application. It is also noted that the discussion above regarding substrate 110, transition body 122, buffer layer 124, device channel layer 142, and device barrier layer 144 applies respectively to the substrates, transition bodies, buffer layers, device channel layers, and device barrier layers in various other implementations of the present disclosure, such as those discussed in relation to FIGS. 2, 3A, 3B, 5, 6A, and 6B below.

Thus, as disclosed in the present application, the degradation in performance seen in group III-V devices such as III-Nitride HEMTs due to charge trapping in conventional device structures is reduced or substantially eliminated due to a shielding element formed below the device 2-DEG. According to the exemplary implementation shown in FIG. 1, for example, shield 2-DEG 136 produced by shield barrier layer 134 and shield channel layer 132 substantially shields device 2-DEG 146 from charge centers 190 and 192 situated between substrate 110 and shield 2-DEG 136.

Referring to FIG. 2, FIG. 2 shows a cross-sectional view of exemplary group III-V device 200 including a shield layer configured to shield the device 2-DEG from charge centers situated in the device structure, according to one implementation. As shown in FIG. 2, group III-V device 200 includes substrate 210, transition body 222 situated over substrate 210, and first buffer layer 224 situated over transition body 222. In addition, FIG. 2 shows device channel layer 242 situated over transition body 222, and device barrier layer 244 situated over device channel layer 242 to produce device 2-DEG 246. Also shown in FIG. 2 are shield layer 230, and second buffer layer 228 situated between shield layer 230 and device channel layer 242. Moreover, and as further shown in FIG. 2, group III-V device 200 includes drain electrode 202, source electrode 204, and gate electrode 206, and may have charge centers 290 and/or 292 situated between substrate 210 and device channel layer 242.

Substrate 210, transition body 222, first buffer layer 224, and charge centers 290 and 292 correspond in general to substrate 110, transition body 122, buffer layer 124, and charge centers 190 and 192, respectively, in FIG. 1, and may share any of the characteristics attributed to those corresponding features, above. In addition, device channel layer 242, device barrier layer 244, and device 2-DEG 246, in FIG. 2, correspond in general to device channel layer 142, device barrier layer 144, and device 2-DEG 146, respectively, in FIG. 1, and may analogously share any of the characteristics attributed to those corresponding features, above. Moreover, drain electrode 202, source electrode 204, and gate electrode 206, in FIG. 2, correspond in general to drain electrode 102, source electrode 104, and gate electrode 106, respectively, in FIG. 1, and may share any of the characteristics attributed to those corresponding features, above.

Group III-V device 200 having the features shown in FIG. 2 may be implemented as a III-Nitride or other group III-V HEMT or FET device or hybrid FET/HEMT device. Moreover, it is noted that in addition to the features shown in FIG. 2, group III-V device 200 may further include some or all of the strain-absorbing, spacer, and capping layers described above by reference to FIG. 1. For example, group III-V device 200 may include an amorphous silicon nitride strain-absorbing layer between substrate 210 and transition body 222, and/or one or more spacer layers between device channel layer 242 and device barrier layer 244, and/or a group III-V or insulating capping layer over device barrier layer 244, as discussed above.

According to the implementation shown in FIG. 2, device 2-DEG 246 is produced by device barrier layer 244 and device channel layer 242 over second buffer layer 228 and shield layer 230. As a result, shield layer 230 is situated so as to substantially shield device 2-DEG 246 from charge trapping resulting from the presence of charge centers 290 and 292 below shield layer 230. That is to say, shield layer 230 is configured to substantially shield device 2-DEG 246 from charge centers 290 and 292 situated between substrate 210 and shield layer 230.

First buffer layer 224 is situated over transition body 222 and may be a III-Nitride or other group III-V material layer formed using any of MBE, MOCVD, or HVPE, for example. For instance, in implementations in which group III-V device 200 is a GaN based HEMT, first buffer layer 224 may be a compositionally graded GaN based layer, as described above. Moreover, in some implementations, first buffer layer 224 may take the form of a III-Nitride or other group III-V layer including a group III material having an aluminum concentration in a range from approximately four percent to approximately twenty percent, for example an AlGaN layer having such an aluminum concentration.

As shown in FIG. 2, shield layer 230 is formed over first buffer layer 224. Shield layer 230 may be an N doped or P doped III-Nitride or other group III-V layer. In implementations in which shield layer 230 is an N doped layer, shield layer 230 may be formed as a thin GaN or AlGaN layer doped with silicon or germanium, for example. In order to effectively shield device 2-DEG 246 from charge centers 290 and/or 292, the doping concentration of shield layer 230 should be on the order of the carrier concentration of device 2-DEG 246, e.g., approximately 10¹³ charge/cm². As a result, shield layer 230 will typically have a doping concentration of at least approximately 10¹² charge/cm². Shield layer 230 may be formed using any of MBE, MOCVD, or HVPE, for example.

It is noted that although FIG. 2 shows shield layer 230 to be situated over first buffer layer 224, in some implementations it may be advantageous or desirable to situate shield layer 230 below first buffer layer 224. For example, in some implementations, shield layer 230 may be situated in transition body 220, amongst the transition layers forming transition body 220.

It is further noted that although shield layer 230 may be a desirable feature of group III-V device 200 for substantially shielding device 2-DEG 246 from charge centers 290 and 292, it is typically undesirable for shield layer 230 to contribute to the conduction of group III-V device 200. For example, unless suitably isolated from device 2-DEG 246, shield layer 230 may adversely affect the pinch-off voltage, off-state leakage, breakdown, or otherwise impact the performance or reliability of group III-V device 200. As a result, it may be advantageous or desirable to ensure that neither drain electrode 202 nor source electrode 204 makes ohmic contact with shield layer 230, and to electrically isolate device 2-DEG 246 from shield layer 230. According to the implementation shown in FIG. 2, such electrical isolation of device 2-DEG 246 from shield layer 230 is provided by second buffer layer 228.

Second buffer layer 228 may be a III-Nitride or other group III-V material layer formed using any of MBE, MOCVD, or HVPE, for example. For instance, in implementations in which group III-V device 200 is a GaN based HEMT, second buffer layer 228 may be a compositionally graded GaN based layer, as described above. Moreover, in some implementations, second buffer layer 228 may take the form of a III-Nitride or other group III-V layer including a group III material having an aluminum concentration in a range from approximately four percent to approximately twelve percent, for example an AlGaN layer having such an aluminum concentration.

Thus, according to the exemplary implementation shown in FIG. 2, shield layer 230 is configured to substantially shield device 2-DEG 246 from charge centers 290 and 292 situated between substrate 210 and shield layer 230. As a result, the degradation in group III-V device performance due to charge trapping in conventional device structures is reduced or substantially eliminated in group III-V device 200 due to the presence of shield layer 230 below device 2-DEG 246.

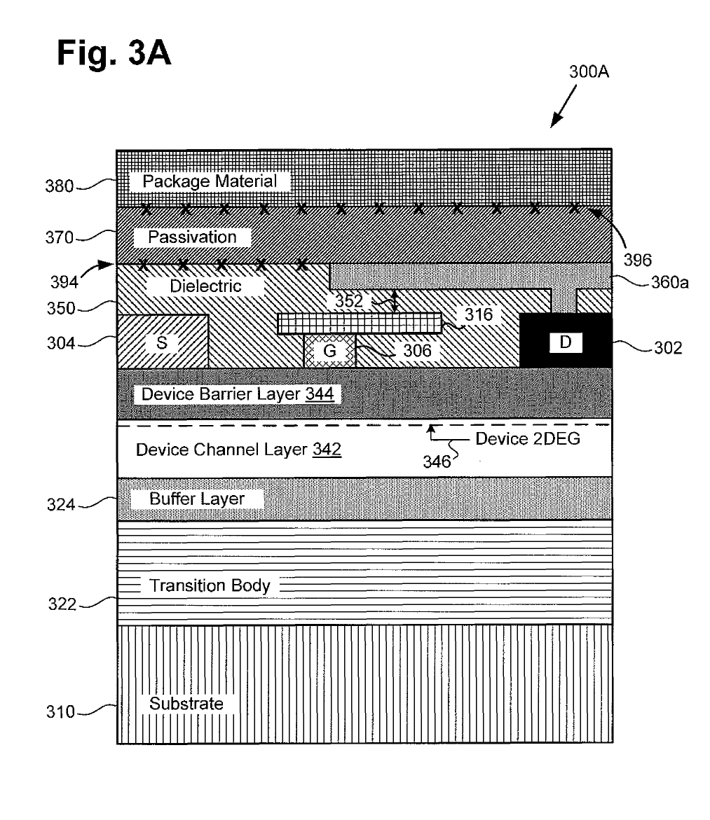

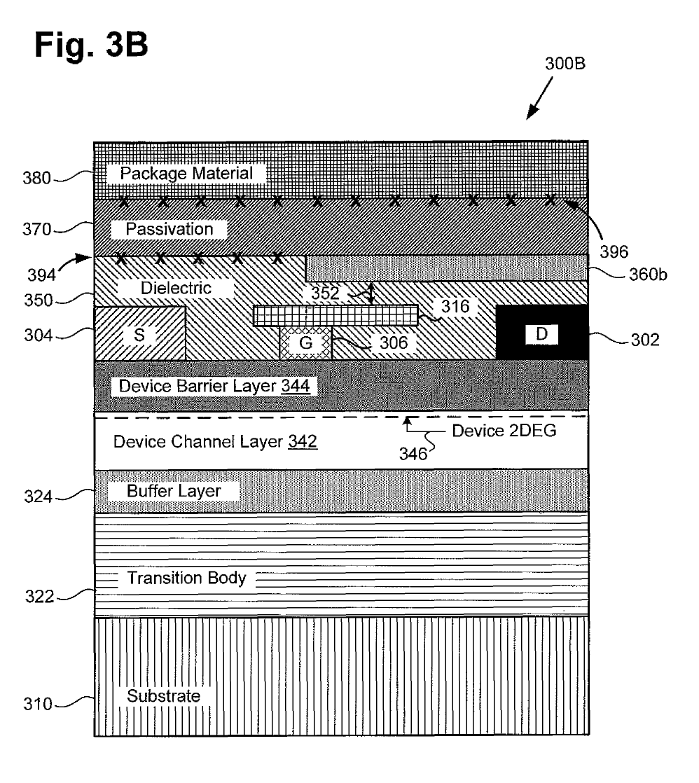

Although the implementations shown in FIG. 1 and FIG. 2 address charge trapping due to charge centers situated below a device 2-DEG, as noted above, charge trapping may also occur due to the presence of charge centers above the device 2-DEG. For example, charge centers may be found in the various material layers formed over the device 2-DEG, such as capping, passivation, field dielectric, and inter-layer dielectric (ILD) layers, as well as at the interfaces of those layers. In addition, charge trapping may occur due to charge centers in the packaging material used to house the group III-V device. FIGS. 3A, 3B, 4A, 4B, 5, 6A, and 6B show exemplary implementations of group III-V devices configured to provide shielding from charge centers situated above the device 2-DEG.

Referring to FIG. 3A, FIG. 3A shows a cross-sectional view of exemplary group III-V device 300A including a shield plate configured to shield device 2-DEG 346 from charge centers 394 and 396 above shield plate 360a and field plate 316, according to one implementation. As shown in FIG. 3A, group III-V device 300A includes substrate 310, transition body 322 situated over substrate 310, and buffer layer 324 situated over transition body 322. In addition, FIG. 3A shows device channel layer 342 situated over transition body 322, and device barrier layer 344 situated over device channel layer 342 to produce device 2-DEG 346. Also shown in FIG. 3A are dielectric layer 350, passivation layer 370, and package material 380, all situated above device barrier layer 344. Moreover, and as further shown in FIG. 3A, group III-V device 300A includes drain electrode 302, source electrode 304, gate electrode 306, field plate 316 overlying gate electrode 306, and shield plate 360a coupled to drain electrode 302. In addition, FIG. 3A shows separation thickness 352 of dielectric layer 350 spacing shield plate 360a apart from field plate 316.

Substrate 310, transition body 322, and buffer layer 324 correspond in general to substrate 110, transition body 122, and buffer layer 124, respectively, in FIG. 1, and may share any of the characteristics attributed to those corresponding features, above. In addition, device channel layer 342, device barrier layer 344, and device 2-DEG 346, in FIG. 3A, correspond in general to device channel layer 142, device barrier layer 144, and device 2-DEG 146, respectively, in FIG. 1, and may analogously share any of the characteristics attributed to those corresponding features, above. Moreover, drain electrode 302, source electrode 304, and gate electrode 306, in FIG. 3A, correspond in general to drain electrode 102, source electrode 104, and gate electrode 106, respectively, in FIG. 1, and may share any of the characteristics attributed to those corresponding features, above.

Group III-V device 300A having the features shown in FIG. 3A may be implemented as a III-Nitride or other group III-V HEMT or FET device or hybrid FET/HEMT device. Moreover, it is noted that in addition to the features shown in FIG. 3A, group III-V device 300A may further include some or all of the strain-absorbing, spacer, and capping layers described above by reference to FIG. 1. For example, group III-V device 300A may include an amorphous silicon nitride strain-absorbing layer between substrate 310 and transition body 322, and/or one or more spacer layers between device channel layer 342 and device barrier layer 344, and/or a group III-V or insulating capping layer over device barrier layer 344, as discussed above.

According to the implementation shown in FIG. 3A, device 2-DEG 346 is produced by device barrier layer 344 and device channel layer 342 and is situated under shield plate 360a. As a result, shield plate 360a is situated so as to substantially shield device 2-DEG 346 from charge trapping resulting from the presence of charge centers 394 and 396 above shield plate 360a.

Dielectric layer 350 and passivation layer 370 may be formed of any suitable dielectric materials, and may be formed using any suitable technique known in the art. For example, passivation layer 370 may be a Si₃N₄, layer, while dielectric layer 350 may be implemented using silicon dioxide (SiO₂). Moreover, package material 380 may be any material suitable for use as an encapsulant in semiconductor packaging. For example, package material 380 may be an epoxy resin based molding compound.

As shown in FIG. 3A, formation of dielectric layer 350, passivation layer 370, and package material 380 over device barrier layer 344 can result in the inadvertent formation of charge centers 394 and/or 396. Charge centers 394 and/or 396 may be formed as point defects, such as impurities, vacancies, and interstitials, for example, in the materials used to provide dielectric layer 350, passivation layer 370, and package material 380. Alternatively, or in addition, charge centers 394 and/or 396 may be present in the form of dangling bonds or other charge trapping sites situated at an interface between dielectric layer 350 and passivation layer 370, and/or at an interface between passivation layer 370 and package material 380.

According to the implementation shown in FIG. 3A, shield plate 360a is formed over dielectric 350 and is coupled to drain electrode 302. Shield plate 360a may be an electrically conductive plate, for example, such as a metal plate, or a doped semiconductor plate. For instance, shield plate 360a may take the form of a P doped or N doped group III-V layer or plate having a doping concentration of at least approximately 10¹² charge/cm², such as a doping concentration of approximately 10¹³ charge/cm². Alternatively, shield plate 360a may be a substantially undoped semiconductor plate, or may be implemented as a resistive plate.

In implementations in which semiconductor or resistive shield plates are used, such shield plates may also act as additional field plates, examples of which are disclosed in U.S. patent application Ser. No. 14/531,181, entitled “Group III-V Transistor with Semiconductor Field Plate”, filed on Nov. 3, 2014 and claiming priority to provisional U.S. Patent Application No. 61/910,522, entitled “III-Nitride Transistor with Semiconductive Field Plate”, and filed on Dec. 2, 2013; as well as in U.S. patent application Ser. No. 11/322,923, entitled “III-Nitride Power Semiconductor with a Field Relaxation Feature”, filed on Dec. 30, 2005, and published as U.S. Patent Application Publication Number 2006/0145189 on Jul. 6, 2006. The disclosures in the above-referenced patent applications are hereby incorporated fully by reference into the present application.

As further shown in FIG. 3A, shield plate 360a may extend at least partially over gate electrode 306 and field plate 316. Furthermore, in some implementations, shield plate may be situated over drain electrode 302 and may extend over gate electrode 306, field plate 316, and at least a portion of source electrode 304.

It is noted that shield plate 360a should be configured such that its presence does not adversely impact the performance of group III-V device 300A. That is to say, although shield plate 360a should be configured to substantially shield device 2-DEG 346 from charge centers 394 and 396, shield plate 360a should not contribute to dielectric breakdown of group III-V device 300A within its rated operating voltage range. Consequently, it is important that separation thickness 352 of dielectric layer 350 be such that the breakdown voltage of separation thickness 352 is at least twice the rated voltage (or in certain applications the time weighted average rated voltage in the application) of group III-V device 300A. For example, if the voltage rating of group III-V device 300A is approximately six hundred volts (600V), separation thickness 352 should be such that the dielectric breakdown of dielectric layer 350 at separation thickness 352 is greater than or approximately equal to 1,200V.

It is further noted that although FIG. 3A shows separation thickness 352 as spacing shield plate 360a from field plate 316 overlying gate electrode 306, the presence of field plate 316 is optional. In implementations in which field plate 316 is omitted, separation thickness 352 spaces shield plate 360a from gate electrode 306 so as to electrically isolate gate electrode 306 from shield plate 360a.

Thus, according to the exemplary implementation shown in FIG. 3A, shield plate 360a is configured to substantially shield device 2-DEG 346 from charge centers 394 and 396 situated over shield plate 360a. As a result, the degradation in group III-V device performance due to charge trapping in conventional device structures is reduced or substantially eliminated in group III-V device 300A due to the presence of shield plate 360a.

Continuing to FIG. 3B, FIG. 3B shows a cross-sectional view of exemplary group III-V device 300B including a floating shield plate configured to shield device 2-DEG 346 from charge centers 394 and 396, according to one implementation. It is noted that the features in FIG. 3B identified by reference numbers identical to those appearing in FIG. 3A correspond respectively to those features, as described above, and may share any of the characteristics attributed to those corresponding features, above.

As shown in FIG. 3B, group III-V device 300B differs from group III-V device 300A in FIG. 3A in that the implementation in FIG. 3B utilizes floating shield plate 360b, rather than shield plate 360a, which, as shown in FIG. 3A, is coupled to drain electrode 302. By contrast, floating shield plate 360b is spaced apart from and electrically isolated from drain electrode 302 by dielectric layer 350.

Like group III-V device 300A, however, group III-V device 300B having the features shown in FIG. 3B may be implemented as a III-Nitride or other group III-V HEMT or FET or hybrid FET/HEMT device. Moreover, it is noted that in addition to the features shown in FIG. 3B, group III-V device 300B may further include some or all of the strain-absorbing, spacer, and capping layers described above by reference to FIG. 1. For example, group III-V device 300B may include an amorphous silicon nitride strain-absorbing layer between substrate 310 and transition body 322, and/or one or more spacer to layers between device channel layer 342 and device barrier layer 344, and/or a group III-V or insulating capping layer over device barrier layer 344, as discussed above.

Floating shield plate 360b may be an electrically conductive plate, for example, such as a metal plate, or a doped semiconductor plate. For instance, floating shield plate 360b may take the form of a P doped or N doped group III-V layer or plate having a doping concentration of at least approximately 10¹² charge/cm², such as a doping concentration of approximately 10¹³ charge/cm². Alternatively, floating shield plate 360b may be a substantially undoped semiconductor plate, or may be implemented as a resistive plate. As shown in FIG. 3B, floating shield plate 360b is situated over drain electrode 302 and may extend at least partially over gate electrode 306 and field plate 316. Moreover, in some implementations, floating shield plate 360b may be situated over drain electrode 302 and may extend over gate electrode 306, field plate 316, and at least a portion of source electrode 304.

Thus, according to the exemplary implementation shown in FIG. 3B, floating shield plate 360b is configured to substantially shield device 2-DEG 346 from charge centers 394 and 396 situated over floating shield plate 360b. As a result, the degradation in group III-V device performance due to charge trapping in conventional device structures is reduced or substantially eliminated in group III-V device 300B due to the presence of floating shield plate 360b.

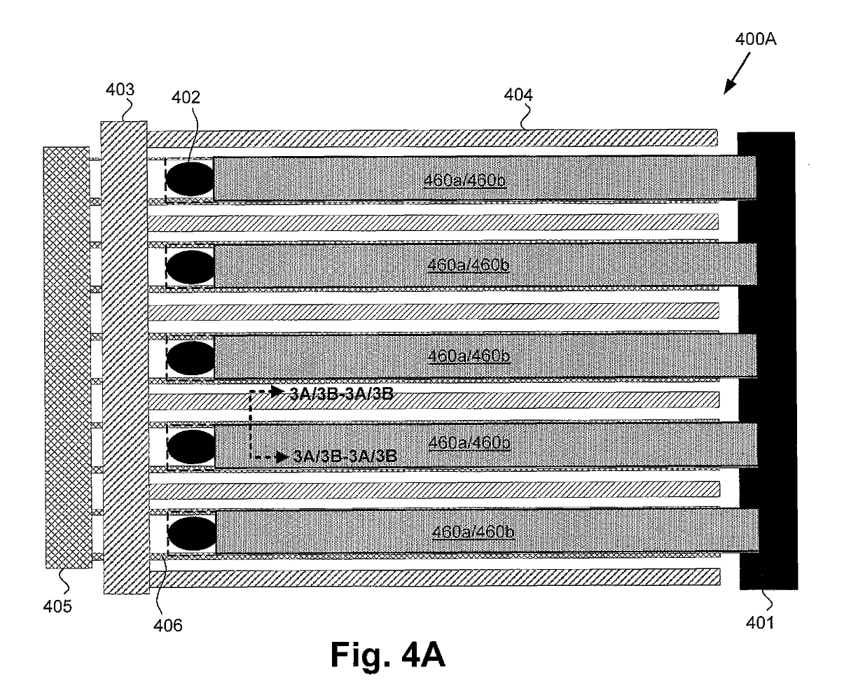

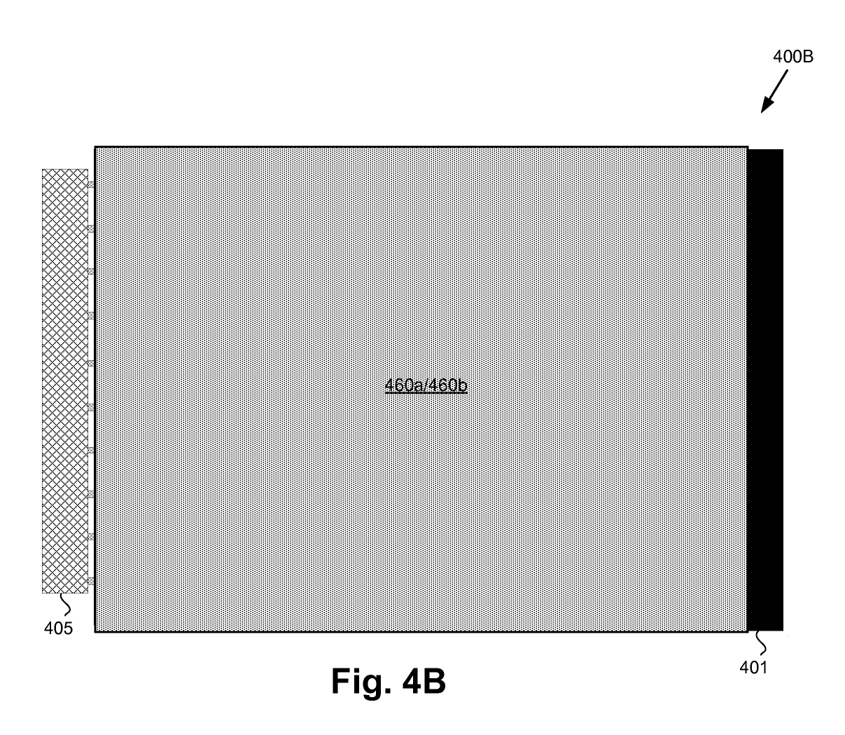

Moving to FIG. 4A and with continued reference to FIGS. 3A and 3B, FIG. 4A shows a top view of an exemplary shield plate arrangement configured to shield device 2-DEG 346 in FIG. 3A and/or FIG. 3B from charge centers situated over device barrier layer 344, according to one implementation. FIG. 4A shows perspective lines 3A/3B-3A/3B depicting the cross-sectional views of structure 400A shown in FIGS. 3A and 3B. In addition, FIG. 4A shows drain fingers 402, source fingers 404, and gate fingers 406 corresponding respectively to drain electrode 302, source electrode 304, and gate electrode 306, in FIGS. 3A and 3B. Also shown in FIG. 4A are shield plates 460a/460b, which may correspond to either of shield plate 360a or floating shield plate 360b shown and described with reference to respective FIGS. 3A and 3B above.

It is noted that FIG. 4A is represented as though seen through package material 380, passivation layer 370, and dielectric layer 350 in FIGS. 3A and 3B. FIG. 4A shows drain runner 401 coupled to drain fingers 402, source runner 403 coupled to source fingers 404, and gate runner 405 coupled to gate fingers 406. It is further noted that the presence of field plates corresponding to field plate 316, in FIGS. 3A and 3B are obscured by shield plates 460a/460b in the representation shown in FIG. 4A.

In FIG. 4A, shield plates 460a/460b extend over the length of each drain finger 402, i.e., as shown by the dashed lines in FIG. 4A extending shield plates 460a/460b over the tips of drain fingers 402. However, in some implementations, it may be advantageous or desirable to terminate shield plates 460a/460b at some distance from the end of the drain finger tips, as shown in FIG. 4A. It is noted that the implementation shown in FIG. 4A utilizes drain finger terminations having an enhanced breakdown ellipsoidal design as disclosed in U.S. patent application Ser. No. 13/749,477, entitled “Transistor Having Increased Breakdown Voltage”, filed on Jan. 24, 2013, and published as U.S. Patent Application Publication Number 2013/0214330 on Aug. 22, 2013. This patent application is hereby incorporated fully by reference into the present application.

According to the implementation shown in FIG. 4A, shield plates 460a/460b are situated over drain fingers 402 and extend at least partially over gate fingers 406. However, in some implementations it may be advantageous or desirable to have shield plates 460a/460b extend over drain fingers 402, gate fingers 406, and source fingers 404. Such an implementation is shown in FIG. 4B.

Referring to FIG. 4B with continued reference to FIGS. 3A, 3B, and 4A, FIG. 4B shows a top view of structure 400B having an exemplary shield plate arrangement configured to shield device 2-DEG 346 in FIG. 3A and/or FIG. 3B from charge centers situated over device barrier layer 344, according to another implementation. Like FIG. 4A, FIG. 4B is represented as though seen through package material 380, passivation layer 370, and dielectric layer 350 in FIGS. 3A and 3B. FIG. 4B shows drain runner 401 and gate runner 405, which are also shown in FIG. 4A.

In contrast to the implementation shown in FIG. 4A, FIG. 4B shows shield plate 460a/460b extending over drain fingers 402, source fingers 404, and gate fingers 406 shown in FIG. 4A but not visible in FIG. 4B. In further contrast to FIG. 4A, according to the implementation shown in FIG. 4B, topside contact cannot be made to source runner 403, which is covered by shield plate 460a/460b. Nevertheless, source runner 403 may be electrically coupled to a conductive substrate of structure 400B (conductive substrate not shown in FIG. 4B) using substrate vias, or may be electrically coupled to the backside of the die providing structure 400B using through-wafer vias (vias also not shown in FIG. 4B).

As an alternative to electrically coupling source runner 403 to the substrate or backside of the die providing structure 400B using through-wafer vias, source runner 403 shown in FIG. 4A can be eliminated through use of source finger vias (i.e., vias located along the length of each source finger 404). In yet other implementations, it may be advantageous or desirable to electrically couple gate fingers 406 to the back side of the die providing structure 400B using various via designs.

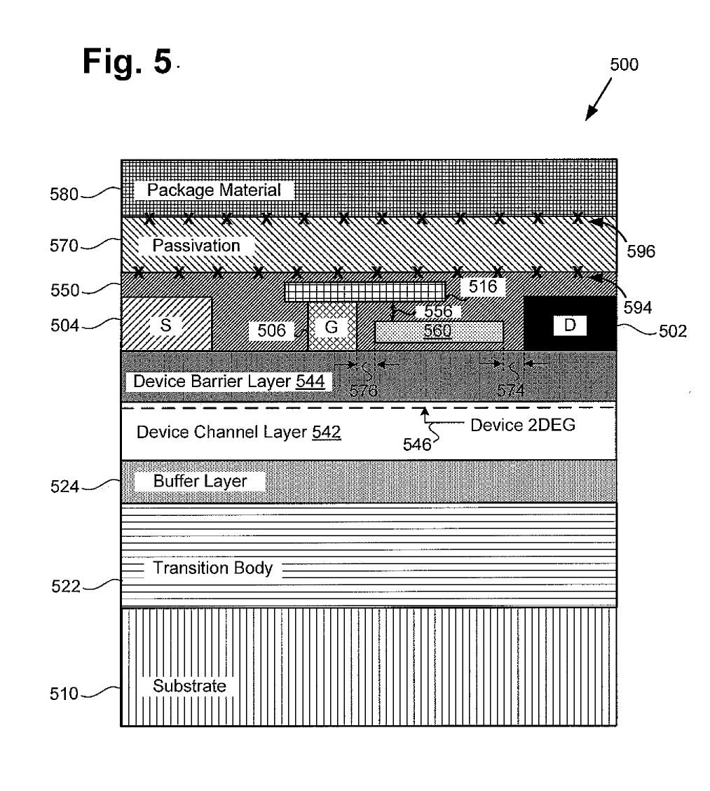

Moving to FIG. 5, FIG. 5 shows a cross-sectional view of exemplary group III-V device 500 including shield plate 560 configured to shield device 2-DEG 546 from charge centers 594 and 596 above shield plate 560, according to one implementation. As shown in FIG. 5, group III-V device 500 includes substrate 510, transition body 522 situated over substrate 510, and buffer layer 524 situated over transition body 522. In addition, FIG. 5 shows device channel layer 542 situated over transition body 522, and device barrier layer 544 situated over device channel layer 542 to produce device 2-DEG 546. Also shown in FIG. 5 are dielectric layer 550, passivation layer 570, and package material 580, all situated above device barrier layer 544.

As further shown in FIG. 5, group III-V device 500 includes drain electrode 502, source electrode 504, gate electrode 506, field plate 516 overlying gate electrode 506, and shield plate 560. It is noted that shield plate 560 may be a floating shield plate, as shown in FIG. 5. In addition, FIG. 5 shows separation thickness 556 of dielectric layer 550 spacing shield plate 560 apart from each of gate electrode 506 and field plate 516. FIG. 5 also shows separation thickness 574 of dielectric layer 550 spacing shield plate 560 apart from drain electrode 502 when shield plate 560 is implemented as a floating shield plate.

Substrate 510, transition body 522, and buffer layer 524 correspond in general to substrate 110, transition body 122, and buffer layer 124, respectively, in FIG. 1, and may share any of the characteristics attributed to those corresponding features, above. In addition, device channel layer 542, device barrier layer 544, and device 2-DEG 546, in FIG. 5, correspond in general to device channel layer 142, device barrier layer 144, and device 2-DEG 146, respectively, in FIG. 1, and may analogously share any of the characteristics attributed to those corresponding features, above.

Drain electrode 502, source electrode 504, and gate electrode 506, in FIG. 5, correspond in general to drain electrode 102, source electrode 104, and gate electrode 106, respectively, in FIG. 1, and may share any of the characteristics attributed to those corresponding features, above. Moreover, field plate 516, dielectric layer 550, passivation layer 570, and package material 580, in FIG. 5, correspond in general to field plate 316, passivation layer 370, dielectric layer 350, and package material 380, in FIGS. 3A and 3B, and may share any of the characteristics attributed to those corresponding features, above.

Group III-V device 500 having the features shown in FIG. 5 may be implemented as a III-Nitride or other group III-V HEMT or FET or hybrid FET/HEMT device. Moreover, it is noted that in addition to the features shown in FIG. 5, group III-V device 500 may further include some or all of the strain-absorbing, spacer, and capping layers described above by reference to FIG. 1. For example, group III-V device 500 may include an amorphous silicon nitride strain-absorbing layer between substrate 510 and transition body 522, and/or one or more spacer layers between device channel layer 542 and device barrier layer 544, and/or a group III-V or insulating capping layer over device barrier layer 544, as discussed above.

According to the implementation shown in FIG. 5, device 2-DEG 546 is produced by device barrier layer 544 and device channel layer 542 and is situated under shield plate 560. As a result, shield plate 560 is situated so as to substantially shield device 2-DEG 546 from charge trapping resulting from the presence of charge centers 594 and 596 above shield plate 560.

As shown in FIG. 5, formation of dielectric layer 550, passivation layer 570, and package material 580 over device barrier layer 544 can result in the inadvertent formation of charge centers 594 and/or 596. Charge centers 594 and/or 596 may be formed as point defects, such as impurities, vacancies, and interstitials, for example, in the materials used to provide dielectric layer 550, passivation layer 570, and package material 580. Alternatively, or in addition, charge centers 594 and/or 596 may be present in the form of dangling bonds or other charge trapping sites situated at an interface between dielectric layer 550 and passivation layer 570, and/or at an interface between passivation layer 570 and package material 580.

According to the implementation shown in FIG. 5, shield plate 560 is a floating shield plate situated adjacent drain electrode 502, and between gate electrode 506 and drain electrode 502. In addition, as shown in FIG. 5, in some implementations, shield plate 560 extends at least partially below field plate 516. Shield plate 560 may be an electrically conductive plate, for example, such as a metal plate, or a doped semiconductor plate. For instance, shield plate 560 may take the form of a P doped or N doped group III-V layer or plate having a doping concentration of at least approximately 10¹² charge/cm², such as a doping concentration of approximately 10¹³ charge/cm². Alternatively, shield plate 560 may be a substantially undoped semiconductor plate, or may be implemented as a resistive plate.

It is noted that shield plate 560 should be configured such that its presence does not adversely impact the performance of group III-V device 500. That is to say, although shield plate 560 should be configured to substantially shield device 2-DEG 546 from charge centers 594 and 596, shield plate 560 should not contribute to dielectric breakdown of group III-V device 500 within its rated operating voltage range. Consequently, it is important that separation thickness 556 of dielectric layer 550 be such that the breakdown voltage of separation thickness 556 is at least twice the rated voltage (or in certain applications the time average rated voltage in the application) of group III-V device 500. For example, if the voltage rating of group III-V device 500 is approximately 600V, separation thickness 556 should be such that the dielectric breakdown of dielectric layer 550 at separation thickness 556 is greater than or approximately equal to 1,200V. As a specific example, separation thickness 556, as well as separation thickness 574 when present, may be in a range from approximately 0.5 micrometer to approximately 1.0 micrometer.

Thus, according to the exemplary implementation shown in FIG. 5, shield plate 560 is configured to substantially shield device 2-DEG 546 from charge centers 594 and 596 situated over shield plate 560. As a result, the degradation in group III-V device performance due to charge trapping in conventional device structures is reduced or substantially eliminated in group III-V device 500 due to the presence of shield plate 560.

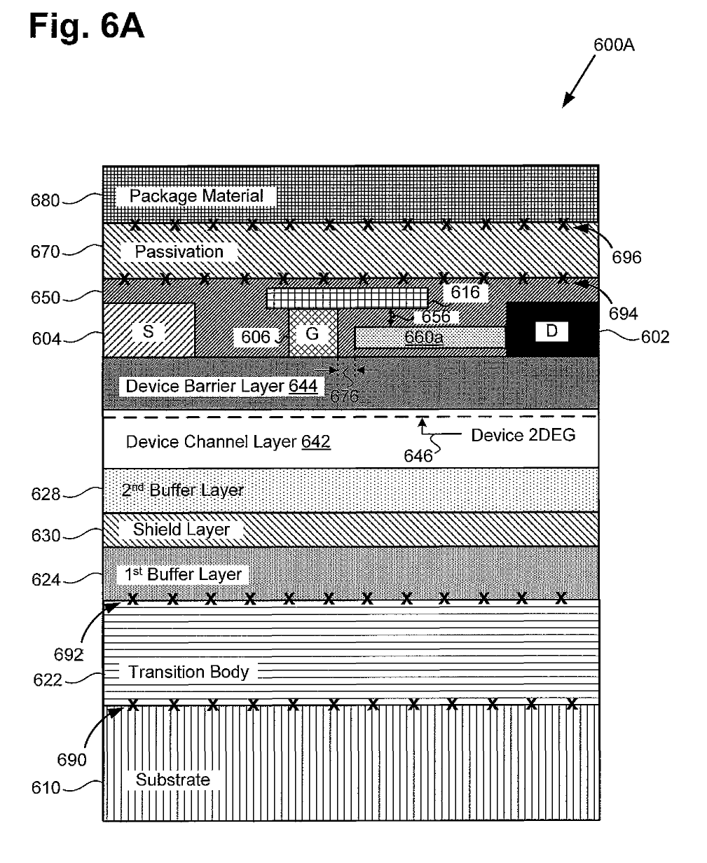

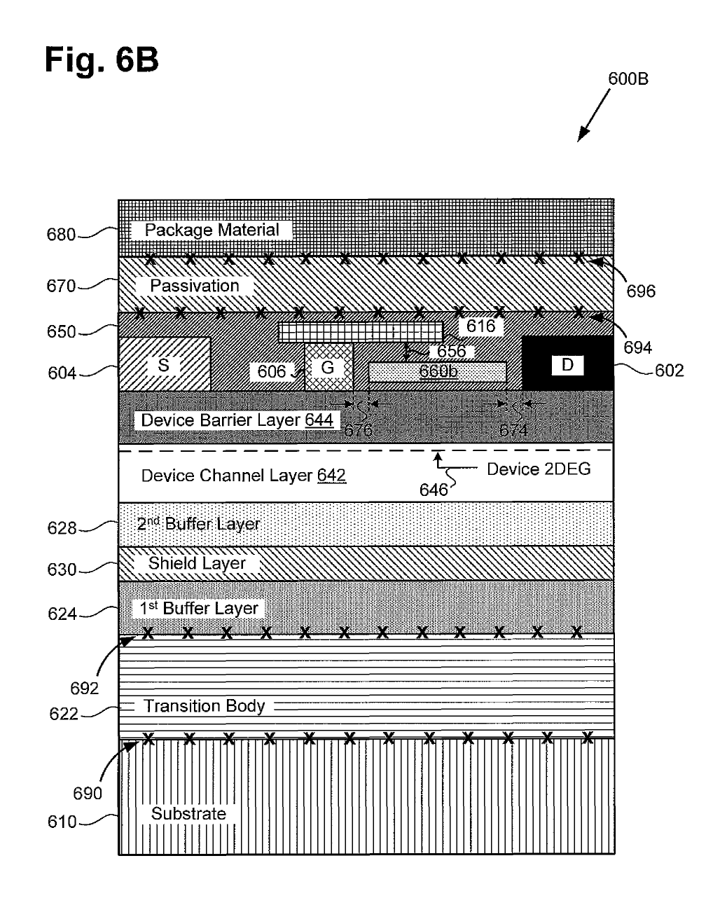

Referring now to FIG. 6A, FIG. 6A shows a cross-sectional view of exemplary group III-V device 600A including a shield plate configured to shield device 2-DEG 646 from charge centers 694 and 696 above device 2-DEG 646, as well as a shield layer configured to shield device 2-DEG 646 from charge centers 690 and 692 below device 2-DEG 646, according to one implementation. As shown in FIG. 6A, group III-V device 600A includes substrate 610, transition body 622 situated over substrate 610, and first buffer layer 624 situated over transition body 622. In addition, FIG. 6A shows device channel layer 642 situated over transition body 622, and device barrier layer 644 situated over device channel layer 642 to produce device 2-DEG 646. Also shown in FIG. 6A are shield layer 630, and second buffer layer 628 situated between shield layer 630 and device channel layer 642. FIG. 6A further shows dielectric layer 650, passivation layer 670, and package material 680, all situated above device barrier layer 644.

As also shown in FIG. 6A, group III-V device 600A includes drain electrode 602, source electrode 604, gate electrode 606, field plate 616 overlying gate electrode 606, and shield plate 660a coupled to drain electrode 602. It is noted that shield plate 660a may be situated between gate electrode 606 and drain electrode 602, as shown in FIG. 6A. In addition, FIG. 6A shows separation thickness 656 of dielectric layer 650 spacing shield plate 660a apart from each of gate electrode 606 and field plate 616. Moreover, and as further shown in FIG. 6A, group III-V device 600A may have charge centers 690 and/or 692 situated between substrate 610 and device channel layer 642, as well as charge centers 694 and/or 696 situated over device barrier layer 644.

Substrate 610, transition body 622, first buffer layer 624, and charge centers 690 and 692 correspond in general to substrate 110, transition body 122, buffer layer 124, and charge centers 190 and 192, respectively, in FIG. 1, and may share any of the characteristics attributed to those corresponding features, above. In addition, device channel layer 642, device barrier layer 644, and device 2-DEG 646, in FIG. 6A, correspond in general to device channel layer 142, device barrier layer 144, and device 2-DEG 146, respectively, in FIG. 1, and may analogously share any of the characteristics attributed to those corresponding features, above. Moreover, shield layer 630 and second buffer layer 628, in FIG. 6A, correspond in general to respective shield layer 230 and second buffer layer 228, in FIG. 2, and may share any of the characteristics attributed to those corresponding features, above.

Drain electrode 602, source electrode 604, and gate electrode 606, in FIG. 6A, correspond in general to drain electrode 102, source electrode 104, and gate electrode 106, respectively, in FIG. 1, and may share any of the characteristics attributed to those corresponding features, above. In addition, field plate 616, dielectric layer 650, passivation layer 670, and package material 680, in FIG. 6A, correspond in general to field plate 316, passivation layer 370, dielectric layer 350, and package material 380, in FIGS. 3A and 3B, and may share any of the characteristics attributed to those corresponding features, above. Furthermore, charge centers 694 and 696 situated over device barrier layer 644, in FIG. 6A correspond in general to respective charge centers 594 and 596, in FIG. 5, and may share any of the characteristics attributed to those corresponding features, above.

Group III-V device 600A having the features shown in FIG. 6A may be implemented as a III-Nitride or other group III-V HEMT or FET or hybrid FET/HEMT device. Moreover, it is noted that in addition to the features shown in FIG. 6A, group III-V device 600A may further include some or all of the strain-absorbing, spacer, and capping layers described above by reference to FIG. 1. For example, group III-V device 600A may include an amorphous silicon nitride strain-absorbing layer between substrate 610 and transition body 622, and/or one or more spacer layers between device channel layer 642 and device barrier layer 644, and/or a group III-V or insulating capping layer over device barrier layer 644, as discussed above.

According to the implementation shown in FIG. 6A, device 2-DEG 646 is produced by device barrier layer 644 and device channel layer 642 and is situated over shield layer 630 and under shield plate 660a. As a result, shield layer 630 is situated so as to substantially shield device 2-DEG 646 from charge trapping resulting from the presence of charge centers 690 and 692 below device 2-DEG 646, while shield plate 660a is situated so as to substantially shield device 2-DEG 646 from charge trapping resulting from the presence of charge centers 694 and 696 above device 2-DEG 646. That is to say, shield layer 630 is configured to substantially shield device 2-DEG 646 from charge centers 690 and 692 situated between substrate 610 and shield layer 630, and shield plate 660a is configured to substantially shield device 2-DEG 646 from charge centers 694 and 696 situated over shield plate 660a.

Shield plate 660a may be an electrically conductive plate, for example, such as a metal plate, or a doped semiconductor plate. For instance, shield plate 660a may take the form of a P doped or N doped group III-V layer or plate having a doping concentration of at least approximately 10¹² charge/cm², such as a doping concentration of approximately 10¹³ charge/cm². Alternatively, shield plate 660a may be a substantially undoped semiconductor plate, or may be implemented as a resistive plate.

It is noted that shield plate 660a should be configured such that its presence does not adversely impact the performance of group III-V device 600A. That is to say, although shield plate 660a should be configured to substantially shield device 2-DEG 646 from charge centers 694 and 696, shield plate 660a should not contribute to dielectric breakdown of group III-V device 600A within its rated operating voltage range. Consequently, it is important that separation thickness 656 of dielectric layer 650 be such that the breakdown voltage of separation thickness 656 is at least twice the rated voltage (or in certain applications the time average rated voltage in the application) of group III-V device 600A. For example, if the voltage rating of group III-V device 600A is approximately 600V, separation thickness 656 should be such that the dielectric breakdown of dielectric layer 650 at separation thickness 656 is greater than or approximately equal to 1,200V. As a specific example, separation thickness 656 may be in a range from approximately 0.5 micrometer to approximately 1.0 micrometer.

Thus, according to the exemplary implementation shown in FIG. 6A, shield layer 630 is configured to substantially shield device 2-DEG 646 from charge centers 690 and 692 situated between substrate 610 and shield layer 630, while shield plate 660a is configured to substantially shield device 2-DEG 646 from charge centers 694 and 696 situated over shield plate 660a. As a result, the degradation in group III-V device performance due to charge trapping in conventional device structures is reduced or substantially eliminated in group III-V device 600A due to the presence of shield layer 630 and shield plate 660a.

Continuing to FIG. 6B, FIG. 6B shows a cross-sectional view of exemplary group III-V device 600B including shield layer 630 and a floating shield plate, which together are configured to shield device 2-DEG 646 from charge centers 690, 692, 694 and 696, according to one implementation. It is noted that the features in FIG. 6B identified by reference numbers identical to those appearing in FIG. 6A correspond respectively to those features, as described above, and may share any of the characteristics attributed to those corresponding features, above.

As shown in FIG. 6B, group III-V device 600B differs from group III-V device 600A in FIG. 6A in that the implementation in FIG. 6B utilizes floating shield plate 660b, rather than shield plate 660a, which, as shown in FIG. 6A, is coupled to drain electrode 602. By contrast, floating shield plate 660b is spaced apart from and electrically isolated from drain electrode 602 by separation thickness 674 of dielectric layer 650, which, for example, may be a separation thickness in a range from approximately 0.5 micrometer to approximately 1.0 micrometer.

Like group III-V device 600A, however, group III-V device 600B having the features shown in FIG. 6B may be implemented as a III-Nitride or other group III-V HEMT or FET or hybrid FET/HEMT device. Moreover, it is noted that in addition to the features shown in FIG. 6B, group III-V device 600B may further include some or all of the strain-absorbing, spacer, and capping layers described above by reference to FIG. 1. For example, group III-V device 600B may include an amorphous silicon nitride strain-absorbing layer between substrate 610 and transition body 622, and/or one or more spacer layers between device channel layer 642 and device barrier layer 644, and/or a group III-V or insulating capping layer over device barrier layer 644, as discussed above.

Floating shield plate 660b may be an electrically conductive plate, for example, such as a metal plate, or a doped semiconductor plate. For instance, floating shield plate 660b may take the form of a P doped or N doped group III-V layer or plate having a doping concentration of at least approximately 10¹² charge/cm², such as a doping concentration of approximately 10¹³ charge/cm². Alternatively, floating shield plate 660b may be a substantially undoped semiconductor plate, or may be implemented as a resistive plate. According to the implementation shown in FIG. 6B, floating shield plate 660b is situated between gate electrode 606 and drain electrode 602. In addition, as shown in FIG. 6B, in some implementations, floating shield plate 660b extends at least partially below field plate 616.

According to the exemplary implementation shown in FIG. 6B, shield layer 630 is configured to substantially shield device 2-DEG 646 from charge centers 690 and 692 situated between substrate 610 and shield layer 630, while floating shield plate 660b is configured to substantially shield device 2-DEG 646 from charge centers 694 and 696 situated over floating shield plate 660b. As a result, the degradation in group III-V device performance due to charge trapping in conventional device structures is reduced or substantially eliminated in group III-V device 600B due to the presence of shield layer 630 and floating shield plate 660b.

Thus, the present application discloses group III-V devices configured such that the disadvantages associated with charge trapping in conventional device structures are reduced or substantially eliminated. According to various implementations of the present inventive concepts, one or more shield elements may be formed in the structure providing the group III-V device. In some implementations, such a shield element may be configured to substantially shield the device 2-DEG from charge centers situated over the device barrier layer. Moreover, in some implementations, such a shielding element may take the form of a shield plate disposed over the device 2-DEG.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described herein, but many rearrangements, modifications, and substitutions are possible without departing from the scope of the present disclosure.

1. A group III-V device comprising:
a substrate;
a transition body situated over said substrate;
a device channel layer situated over said transition body, and a device barrier layer situated over said device channel layer thereby producing a device two-dimensional electron gas (2DEG);
a drain electrode of said group III-V device coupled to said device barrier layer;
a shield plate coupled to said drain electrode, said shield plate configured to substantially shield said device 2DEG from charge centers situated over said device barrier layer.

2. The group III-V device of claim 1, wherein said shield plate is situated over said drain electrode.

3. The group III-V device of claim 1, wherein said shield plate comprises a metal plate.

4. The group III-V device of claim 1, further comprising a gate electrode, wherein said shield plate extends at least partially over said gate electrode.

5. The group III-V device of claim 1, further comprising a gate electrode and a field plate overlying said gate electrode, wherein said shield plate extends at least partially over said field plate.

6. The group III-V device of claim 1, wherein said shield plate comprises a doped group III-V layer having a doping concentration of at least approximately 10¹² charge/cm².

7. The group III-V device of claim 1, further comprising a gate electrode, wherein said shield plate is situated between said gate electrode and said drain electrode.

8. The group III-V device of claim 1, wherein said shield plate comprises a semiconductor plate.

9. The group III-V device of claim 1, wherein said shield plate comprises a resistive plate.

10. The group III-V device of claim 1, wherein said group III-V device comprises a III-Nitride high electron mobility transistor (HEMT).

11. A group III-V device comprising:
a substrate;
a transition body situated over said substrate;
a device channel layer situated over said transition body, and a device barrier layer situated over said device channel layer thereby producing a device two-dimensional electron gas (2DEG);
a drain electrode of said group III-V device coupled to said device barrier layer;
a floating shield plate being adjacent to said drain electrode, said floating shield plate configured to substantially shield said device 2DEG from charge centers situated over said device barrier layer.

12. The group III-V device of claim 11, further comprising a gate electrode, wherein said floating shield plate is situated between said gate electrode and said drain electrode.

13. The group III-V device of claim 11, wherein said floating shield plate comprises a metal plate.

14. The group III-V device of claim 11, further comprising a gate electrode and a field plate overlying said gate electrode, wherein said floating shield plate extends at least partially below said field plate.

15. The group III-V device of claim 11, wherein said floating shield plate comprises a doped group III-V layer having a doping concentration of at least approximately 10¹² charge/cm².

16. The group III-V device of claim 11, wherein said floating shield plate comprises a semiconductor plate.

17. The group III-V device of claim 11, wherein said floating shield plate comprises a resistive plate.

18. The group III-V device of claim 11, wherein said floating shield plate is situated over said drain electrode.

19. The group III-V device of claim 11, further comprising a gate electrode, wherein said floating shield plate extends at least partially over said gate electrode.

20. The group III-V device of claim 11, wherein said group III-V device comprises a III-Nitride high electron mobility transistor (HEMT).
